(19) United States
(12) Patent Application Publication
(10) Pub. No.: US 2011/0204768 A1
(43) Pub. Date: Aug. 25, 2011

(54) LIGHT EMITTING SUBSTRATE, MANUFACTURING METHOD THEREOF, AND IMAGE DISPLAY APPARATUS HAVING THE LIGHT EMITTING SUBSTRATE

(75) Inventor: Yoshihiro Yanagisawa, Fujisawa-shi (JP)

(73) Assignee: CANON KABUSHIKI KAISHA, Tokyo (JP)

(21) Appl. No.: 13/030,991

(22) Filed: Feb. 18, 2011

(30) Foreign Application Priority Data
Feb. 25, 2010 (JP) 2010-039551

(51) Int. Cl. H01J 1/62; B05D 5/06; G03F 7/20

(52) U.S. Cl. 313/498; 427/66; 430/321

(57) ABSTRACT

A light emitting substrate includes a light emitting layer which emits light in response to the bombardment of electrons. A novel rib structure including a pattern of wall-like ribs and sheet-like ribs prevents the collapse of ribs in a finely-pitched pixel layout of the light emitting substrate. A light shielding layer is formed on a substrate, and wall ribs are formed on the light shielding layer. Then, a positive photo paste is spread thereon and exposed to light and then developed, so that sheet ribs having side surfaces tilting toward openings of the light shielding layer are formed.

### BACKGROUND OF THE INVENTION

1. Field of the Invention

The present invention relates to a light emitting substrate having a light emitting layer which emits light in response to electrons bombarded thereon, a manufacturing method of the light emitting substrate, and an image display apparatus provided with the light emitting substrate which is used in, for example, a television.

2. Description of the Related Art

Flat panel displays (FPDs), also referred to as flatscreen displays, are well known and are commercially available in several forms and applications. As examples of a flat panel display currently available which displays an image utilizing light emission generated by the bombardment of electrons, a plasma display (PDP) and a field emission display (FED) are known.

Some of these display apparatuses may adopt a rib (partition wall) structure to partition a discharge cell. For the purpose of improving the efficiency of light emission in the rib structure, ribs are desirably formed to be heightened to increase a surface area of a fluorescent member contributing to discharge-induced light emission. Further, in order to achieve a higher definition in image display, ribs desirably have a small width to optimize the density of display pixels. As a consequence, it is necessary that the ribs be formed in such a shape that an aspect ratio is high.

The ribs formed in any shape having a high aspect ratio, however, are likely to collapse when the image display apparatus is built. There have been so far technical approaches to prevent the possible collapse of ribs. Japanese Patent Application Laid-Open No. 2004-111302 discusses an image display apparatus where a rib structure having a winding shape with bent sections is provided to prevent any external force from acting on the ribs, causing them to collapse. Japanese Patent Application Laid-Open No. 2001-23515 discusses an image display apparatus wherein auxiliary ribs are additionally formed in a rib structure to increase a total area where the ribs are joined so that increased structural strength is obtained. Japanese Patent Application Laid-Open No. 2001-118512 discusses an image display apparatus provided with bilayered partition walls having a lower partition wall section formed on a substrate surface and an upper partition wall section formed on the lower partition wall section, wherein the whole of the lower partition wall sections of the lengthwise partition walls in parallel with address electrodes and the crosswise partition walls in parallel with bus electrodes constitutes the lower partition wall sections.

However, the rib structure discussed in Japanese Patent Application Laid-Open No. 2004-111302 which employs a winding pattern layout inevitably demands a larger width as a dedicated area of the ribs formed on the substrate surface, making it difficult to accomplish densely spaced pixel pitches. In the rib structures discussed in the Patent Application Laid-Open No. 2001-23515 and Patent Application Laid-Open No. 2001-118512, it is necessary in laying out a back plate pattern to avoid any interference with address electrodes when the ribs are formed. More specifically, it is required in these apparatuses to ensure such a dimensional margin that can avoid any overlap with the width of the address electrodes and accordingly form the ribs with a smaller width so that the function of the address electrodes on the back plate of, for example, plasma display is not undermined. As a result, these apparatuses cannot provide a width large enough to ensure the necessary structural strength. In the formation of a light emitting substrate having the rib structure, multiple layers are stacked on one another. This structure raises another problem that the rib structure, which is the upper layer, may be restricted to prevent the functional capability of the lower layer from deteriorating.

### SUMMARY OF THE INVENTION

The present invention is directed to a rib structure having a remarkable strength that can prevent ribs from collapsing in a finely-pitched pixel layout, in an image display apparatus provided with a light emitting substrate having a light emitting layer which emits light in response to electrons bombarded thereon, and to an image display apparatus having a distinguished display property which accomplishes a high definition in image display.

According to an aspect of the present invention, a light emitting substrate includes a substrate, a rib structure provided on a surface of the substrate which divides the surface of the substrate into a plurality of regions, and a light emitting layer which emits light in response to electrons bombarded thereon provided in the regions divided by the rib structure, wherein a light shielding layer having a plurality of openings in contact with the surface of the substrate is further provided, and the rib structure includes a wall rib formed between the openings of the light shielding layer and a sheet rib in contact with the wall rib to cover an overall area of the light shielding layer except for the openings, and having a height smaller than a height of the wall rib.

According to another aspect of the present invention, an image display apparatus includes an electron source substrate having a plurality of electron emitting elements, and a light emitting substrate having a light emitting layer which emits light in response to electrons emitted from the plurality of electron emitting elements and bombarded on the light emitting layer.

According to yet another aspect of the present invention, a manufacturing method of a light emitting substrate includes forming a light shielding layer having a plurality of openings on a surface of a substrate, forming between the openings of the light shielding layer a wall rib having a width smaller than a dimension between the adjacent openings; forming a sheet rib in contact with the wall rib to cover an overall area of the light shielding layer except for the openings, and forming a light emitting layer in regions of the substrate divided by the rib structure.

According to the present invention, wherein the wall rib and the sheet rib are combined to constitute the rib structure, the risk of collapse of the ribs can be eliminated even in a densely-pitched pixel layout. In the production of the rib structure, the light shielding layer is used as a mask to expose the substrate to light from the rear surface thereof so that the sheet rib can be self-aligned to the openings of the light shielding layer, which further improves the definition in image display. When the substrate is exposed to light from the rear surface thereof, the wall surface of the sheet rib is formed tilting toward the openings of the light shielding layer. When the light emitting layer is formed, therefore, the effect of self alignment facilitates the formation of the light emitting layer having an equal film thickness. Thus, the present invention can provide an image display apparatus having a distinguished display property which achieves a high definition in image display.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 schematically illustrates cross sections showing steps of forming a rib structure of a light emitting substrate according to the present invention.

FIG. 2 schematically illustrates a cross section showing an example of the light emitting substrate according to the present invention.

FIGS. 3A and 3B schematically illustrate an image display apparatus according to the present invention and an electron source substrate used in the image display apparatus.

### DESCRIPTION OF THE EMBODIMENTS

Various exemplary embodiments, features, and aspects of the invention will be described in detail below with reference to the drawings. The conventional technology well-known to or well-employed by the ordinarily skilled in the relevant technical field is applied to parts of the technical process or matters which are not illustrated or described in the specification.

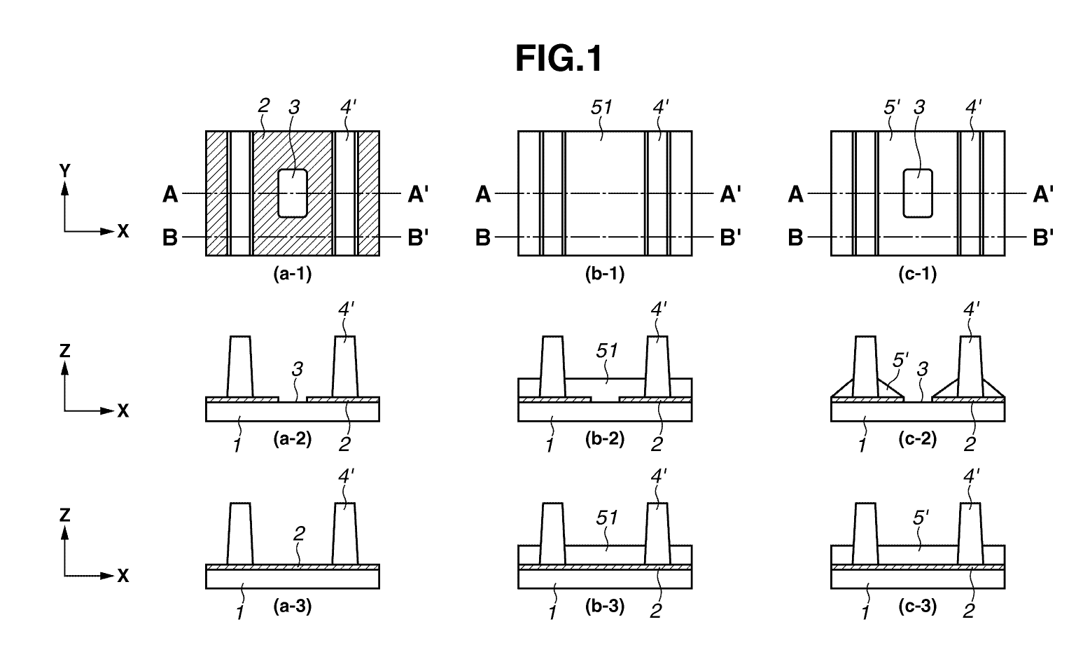

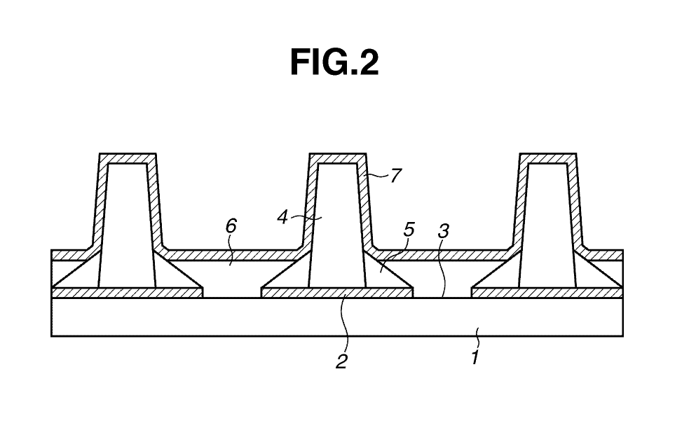

Referring to FIGS. 1 and 2, a structure of a light emitting substrate according to the present invention and a manufacturing method of the light emitting substrate are described in order of manufacture processing. FIG. 2 schematically illustrates a cross section as an example of the light emitting substrate according to the present invention. The emitting substrate includes a substrate 1, a light shielding layer 2, an opening 3 formed in the light shielding layer 2, a wall rib 4, a sheet rib 5, a light emitting layer 6, and a metal back layer 7 as illustrated in FIG. 2. FIG. 1 schematically illustrates cross sections in processing for forming the light emitting substrate illustrated in FIG. 2. In FIGS. 2, (a-2), (b-2), and (c-2) are respectively sectional views of (a-1), (b-1), and (c-1) cut along A-A′, and (a-3), (b-3), and (c-3) are respectively sectional views of (a-1), (b-1), and (c-1) cut along B-B′. FIG. 2 is a cross-sectional schematic illustration of (a-3), (b-3), and (c-3) illustrated in FIG. 1.

As illustrated in (a-1) to (a-3), the light shielding layer 2 having a plurality of openings 3 is formed on a surface (main surface) of the substrate 1. A member which transmits a visible light therethrough, such as a glass substrate, is used as the substrate 1. To form the substrate 1, a glass with a high strain point, for example, “PD200” supplied by ASAHI GLASS CO., LTD is suitably used. In the present exemplary embodiment, the light shielding layer 2 is a black matrix in which openings 3 are provided in the form of dots in the directions of both X and Y. Another applicable example in the present invention is a black stripe having a plurality of linear openings formed in a direction.

In the formation of the light shielding layer 2, photolithography, for example, is suitably employed. However, the formation technique of the shielding layer 2 is not necessarily limited thereto. More specifically, a surface of the substrate 1 is coated with a photo paste containing therein as its principal ingredients, a black inorganic pigment, a glass element, a solvent, a photosensitive resin, and a photo-polymerization initiator. The photo paste is spread on the surface of the substrate 1 preferably by a technique or a device, such as screen printing or a slit coater; however, the technique or device that can be employed is not necessarily limited thereto. Next, a photo mask pattern corresponding to a desired pattern of openings 3 is used to expose the photo paste to light (e.g., for a curing process). The photo paste is then dipped in a developing solution to dissolve and remove any unnecessary portions, so that a predefined pattern of openings 3 is formed. Then, the photo paste undergoes an incineration process to remove (e.g., to burn off) any organic ingredients remaining within the openings 3. As a result, the light shielding layer 2 having the openings 3 is obtained.

Another option for the formation of the light shielding layer 2 by photolithography is a lift-off method. More specifically, a resist film is spread on all over a surface of the substrate 1 to form a predefined pattern so that the resist film is left in the portions of the light shielding layer 2, which later constitute the openings 3. Then, a thin film which later constitutes the light shielding layer 2 is formed on the substrate 1 by, for example, sputtering or vapor deposition. The substrate is then dipped in a resist film stripping solution so that the resist film is lifted off. As a result, the light shielding layer 2 is obtained.

Another different option that can be employed for the formation of the light shielding layer 2 is: a black thin film 2 is formed on all over a surface of the substrate 1 by, for example, sputtering; a resist film having a predefined pattern is formed on the black thin film by photolithography; and any unnecessary portions of the film are removed therefrom by etching so that a predefined pattern of openings 3 is obtained.

Examples of the black material of the light shielding layer 2 are composite metallic oxides such as titanium, iron, cobalt, and manganese. However, the black material is not necessarily limited to these examples.

Next, the wall rib 4 is formed between the openings 3 of the light shielding layer 2 on the substrate 1. Preferably, the wall rib 4 has a width smaller than a distance between two adjacent openings 3. In the present exemplary embodiment, the wall rib 4 is formed in a striped shape extending along the direction Y of the Figures; however, the present invention is not necessarily limited thereto. The wall rib 4 is formed in a direction which follows the stripe when the light shielding layer 2 is a black stripe. The wall rib 4 may have either of a striped shape along the direction of X or a lattice shape extending in the directions of both X and Y when the light shielding layer 2 is a black matrix.

In the formation of the wall rib 4, photolithography is suitably employed; however, the formation technique is not necessarily limited thereto. When photolithography is employed, a photo paste containing therein as its principal ingredients, a glass element, a solvent, a photosensitive resin, and a photo-polymerization initiator is used. More specifically, a surface of the substrate 1 is coated with the photo paste. The thickness of the photo paste spread on the surface is decided in view of the height of the fired ribs. A preferable range of the thickness is 200 to 500 μm. The photo paste is applied by such a technique or a device as screen printing or a slit coater. The slit coater is preferably used when the desirable thickness is between 200 and 500 μm. Then, a photo mask having a predefined pattern is used for the exposure and development of the substrate coated with the photo paste to dissolve and remove any unnecessary portions, so that a predefined pattern 4′ of wall-like ribs 4 (wall rib pattern) is formed (see FIGS. 1 (a-1) to (a-3)).

Now, the sheet rib 5 is formed adjacent to the bottom of the wall rib 4. More specifically, a pattern 5′ of sheet-like ribs 5 (sheet rib pattern) is formed in accordance with the already formed wall rib pattern 4′ (see FIGS. 1 (c-2)). That is, the sheet rib pattern 5′ contacts the wall rib pattern 4′ to cover an overall area of the light shielding layer 2 except for the openings 3. In the formation of the sheet rib 5, photolithography is suitably employed; however, the formation technique is not necessarily limited thereto. A photo paste used in the photolithography contains therein as its principal ingredients, a glass element, a solvent, a photosensitive resin, and a photo-polymerization initiator. A positive photo paste is used in the present invention, and the photo paste is preferably exposed to light from the rear surface of the substrate 1 by using the light shielding layer 2 as a mask. Below is described a manufacturing method in which the positive photo paste is used.

As a positive photo paste 51 used to form the sheet rib pattern 5′, a diazonaphthoquinone-novolac photosensitive resin is suitably used. The photo paste 51 for forming the sheet rib is spread on all over a surface of the substrate 1 (see FIGS. 1 (b-1) to (b-3)). To apply the photo paste 51, screen printing, a slit coater, or a dispenser method, for example, can be employed; however, the application method is not necessarily limited thereto.

Next, the substrate 1 coated with the photo paste 51 for forming the sheet rib is exposed to light from the rear surface of the substrate 1 and then developed to dissolve and remove any unnecessary portions so that the predefined rib pattern 5′ is formed (see FIGS. 1 (c-1) to (c-3)). When the positive photo paste is used, and the substrate 1 is exposed to light from the rear surface thereof by using the light shielding layer 2 as a mask as described in the present exemplary embodiment, it is unnecessary to separately prepare a dedicated mask for exposure and positionally adjust the mask, thereby simplifying the manufacturing method. The sheet rib pattern 5′ has side surfaces which increasingly tilt as distance from the openings 3 of the light shielding layer 2 increases to increase a degree of opening because the light comes around at the time of exposure, and it becomes easier to perform development toward the center of the opening 3.

Then, organic ingredients included in the wall rib pattern 4′ and the sheet rib pattern 5′ are burnt off, so that the rib structure including the wall ribs 4 and the sheet ribs 5 illustrated in FIG. 2 is formed. In the present exemplary embodiment, the wall rib 4 and the sheet rib 5 are collectively fired to improve the efficiency of the manufacturing method; however, they may be separately fired. According to the present invention, the fired wall rib 4 has a height approximately in the range of 100 to 250 μm and a width approximately in the range of 35 to 100 μm. The sheet rib 5 combined with the wall rib 4 has a height smaller than that of the wall rib 4. The height of the sheet rib 5 is preferably approximately 5 to 40% of the height of the wall rib 4. The sheet rib 5 preferably has a thickness larger than that of the light emitting layer 6.

Next, as illustrated in FIG. 2, the light emitting layer 6 is formed in the regions divided by the rib structure (apertures of the rib structure). To form the light emitting layer 6, screen printing or a dispenser method is suitably employed; however, other suitable method can be employed as well. When the screen printing or dispenser is employed, the light emitting layer 6 can be easily formed when a paste containing therein as its principal ingredients, for example, fluorescent particles of R, G, and B color, a resin, and a solvent is applied to the apertures of the rib structure and fired so that organic ingredients included therein are lost. According to the present exemplary embodiment, wherein the side surfaces of the sheet rib 5 tilt toward the openings of the light shielding layer 2 as described earlier, the materials constituting the light emitting layer 6 gather on the openings 3 of the light shielding layer 2, generating what is generally called, the effect of self alignment. The effect of self alignment decreases the variability of the in-plane film thickness of the light emitting layer 6 in the openings 3 of the light shielding layer 2. The effect of self alignment further serves to prevent the sheet rib 5 from clogging the openings 3 of the light shielding layer 2 when the sheet rib 5 is formed thereon except for the openings 3. Accordingly, the root portion of the wall rib 4 can be strengthened by the sheet rib 5, and a whole area where the ribs are formed can be increased so that a strength is ensured to prevent the ribs from collapsing, and the rib structure where there is no interference between the light shielding layer 2 and the openings 3 can be obtained.

Then, the metal back layer 7 is formed on the rib structure and the light emitting layer 6. For example, vapor deposition is suitably employed in the formation of the metal back layer 7; however, a different technique may be suitably employed as well. A preferable material of the metal back layer 7 is aluminum because it is inexpensive and can be easily handled in the manufacturing processing; however, other suitable material may be used. In the illustration of FIG. 2, the metal back layer 7 is formed on the rib structure and the light emitting layer 6. An alternative way to form the metal back layer 7 is to laminate a dry film resist on portions corresponding to the fluorescent material of the light emitting layer 6 and subject it to patterning so that the metal back layer 7 is formed on the light emitting layer 6 alone.

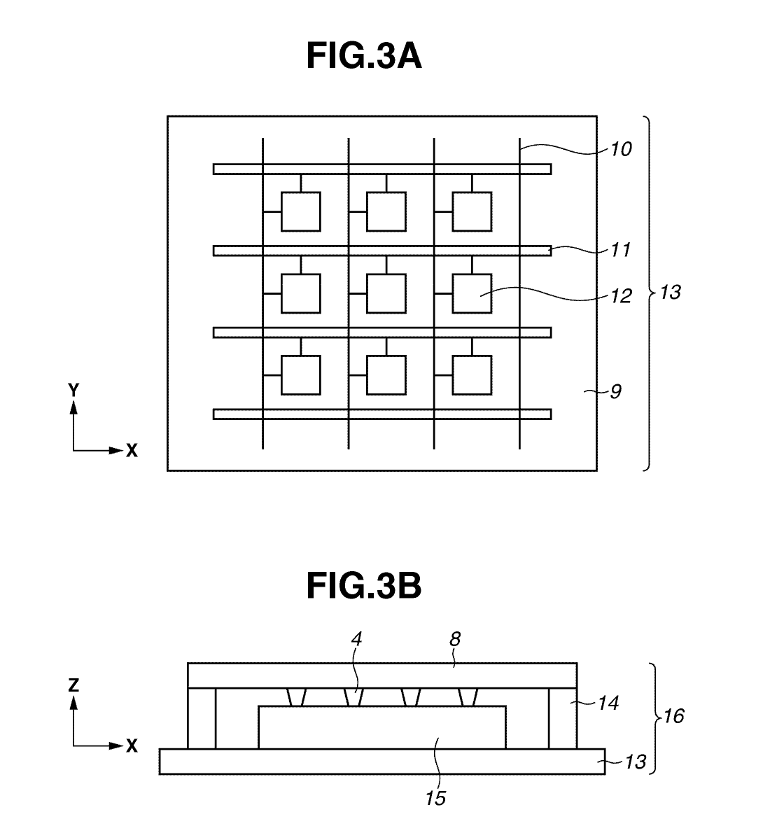

Referring to FIG. 3, an image display apparatus 16 including a light emitting substrate 8 thus formed is described. FIG. 3A is a plan view of an electron source substrate used in the image display apparatus according to the present invention. FIG. 3B is a sectional view schematically illustrating a structure of the image display apparatus according to the present invention.

An electron source substrate 13 used in the present invention has a plurality of electron emitting elements 12 on a substrate 9 as illustrated in FIG. 3A. The elements 12 are connected to a matrix wiring including signal wires 10 and scan wires 11 so that an electron is emitted from a given address by a driving circuit not illustrated in the drawing. The electron emitting element 12 is not particularly limited to any element; however, a preferable example thereof is a surface conduction electron emitting element.

To obtain the image display apparatus 16, as illustrated in FIG. 3B, the electron source substrate 13 having the electron emitting elements 12 and the light emitting substrate 8 are faced with each other and combined so that a vacuum container encompassed with a frame 14 is formed. The light emitting substrate 8 according to the present invention illustrated in FIG. 2 is used as the light emitting substrate 8. FIG. 3B illustrates the wall ribs 4 alone, which is a characteristic element of the structure of the light emitting substrate according to the present invention. The other structural elements are omitted for the sake of simplicity. A spacer 15 is placed in the image display apparatus obtained in the form of a vacuum container to sustain resistance to ambient pressure. The spacer 15 is placed to abut tip portions of the wall ribs 4 of the light emitting substrate 8. A high voltage power is supplied to the light emitting substrate 8 from a high voltage power supply not illustrated in the drawing, and electrons emitted from the electron source substrate 13 are bombarded on the light emitting layer 6 of the light emitting substrate 8 so that the light emitting layer 6 emits light.

So far was described the exemplary embodiment of the present invention. The present invention can adopt various modifications other than the exemplary embodiment within the originally intended scope of the present invention.

The present invention is described in further detail referring to a working example, however, the present invention is not necessarily limited to the working example.

The light emitting substrate 8 was manufactured according to the manufacturing method illustrated in FIG. 1, and the image display apparatus 16 equipped with the light emitting substrate 8 was obtained. The product PD-200 supplied by ASAHI GLASS CO., LTD. was used to obtain the substrate 1. After the substrate 1 was washed with water, the light shielding layer 2 was formed on a surface of the substrate 1. A black paste (NP-7811M1, supplied by NORITAKE CO., LIMITED) was used as a material constituting the light shielding layer 2. The paste was spread on all over the main surface of the substrate 1 by screen printing and exposed to light and then developed using a photo mask having a predefined pattern. The paste was fired at 580° C. so that organic ingredients included in the paste were burnt off. Then, the light shielding layer 2 was formed in the thickness of 5 μm. The light shielding layer 2 has a lattice pattern having the openings 3 arranged in the form of matrix corresponding to the positions where the light emitting layer 6 is to be provided. The pitch of the opening 3 was 150 μm in the direction of X and 450 μm in the direction of Y, and the dimension of the opening 3 was 90 μm in the direction of X and 220 μm in the direction of Y. Then, a distance between the adjacent openings 3 in the direction of Y resulted in 230 μm.

Next, the wall rib 4 extending in the striped shape along the direction of Y was formed between the openings 3 of the light shielding layer 2 on the substrate 1. The material of the wall rib was spread by a slit coater in the thickness of approximately 400 μm and dried at 100° C., and the resulting film was exposed to light and then developed using a photo mask having a predefined pattern, so that the wall rib pattern 4′ was formed (see FIGS. 1 (a-1) to (a-3)).

Next, the sheet rib pattern 5′ was formed to cover the light shielding layer 2 except for the openings 3. First, the positive photo paste 51 was spread by a dispenser device on the entire area other than the wall ribs 4 in the thickness of 60 μm. At the time, a head of the dispenser was scanned along the direction of the stripe of the wall rib 4 so that the sheet rib paste was applied between the adjacent wall ribs 4 (see FIGS. 1 (2-a) to (2-b)). Then, the light shielding layer 2 was used as a mask to expose the paste to light from the rear surface of the substrate 1 and develop it so that the sheet rib paste in the openings 3 of the light shielding layer 2 was melted and lost. As a result, the sheet rib pattern 5′ was formed (see FIGS. 1 (3-a) to (3-c)). Finally, organic ingredients included in the wall rib pattern 4′ and the sheet rib pattern 5′ were burnt off through firing at 580° C. As a result, the rib structure including the wall ribs 4 and the planer ribs 5 was obtained. The height of the fired wall rib 4 was approximately 200 μm, and the width of the bottom section of the wall rib 4 was approximately 75 μm. The sheet rib 5 had the thickness of approximately 30 μm.

As illustrated in FIG. 2, the light emitting layer 6 was formed in the apertures of the rib structure of the substrate 1 on which the wall ribs 4 and the sheet ribs 5 were formed. A paste containing therein as its principal ingredients fluorescent particles, a resin, and a solvent was used as the material of the light emitting layer 6. The paste was applied between the wall ribs 4 by screen printing. The applied paste was fired so that organic ingredients included therein were burnt off at 500° C. As a result, a pattern in which the light emitting layer 6 was provided in the openings 3 of the light shielding layer 2 was obtained. Finally, the metal back layer 7 was formed on the light emitting layer 6 and the rib structure. The metal back layer 7 was made of aluminum and formed by vapor deposition conventionally adopted in the thickness of 150 nm.

Then, the light emitting substrate 8 thus formed and the electron source substrate 13 illustrated in FIG. 3A were put together to form the image display apparatus 16. In the image display apparatus 16, the electron source substrate 13 having the surface conduction electron emitting elements used as the electron emitting elements 12, and the light emitting substrate 8 were faced with each other and combined so that a vacuum container was formed. The spacer 15 was placed within the image display apparatus formed as a vacuum container to sustain resistance to ambient pressure. The spacer 15 was placed abutting tip portions of the wall ribs 4 of the light emitting substrate 8.

According to the image display apparatus 16 manufactured in the present example, the vacuum container was smoothly formed, and collapse of the ribs did not occur. Further, none of the ribs ran over toward the openings 3 of the black matrix 2, and a good display performance was achieved by light emission from the light emitting layer 6 using electrons.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-039551 filed Feb. 25, 2010, which is hereby incorporated by reference herein in its entirety.

What is claimed is:

1. A light emitting substrate comprising:
a substrate;
a rib structure provided on a surface of the substrate which divides the surface of the substrate into a plurality of regions;
a light emitting layer which emits light in response to electrons bombarded thereon, provided in the regions divided by the rib structure; and
a light shielding layer having a plurality of openings in contact with the surface of the substrate,
wherein the rib structure includes a wall rib formed between two adjacent openings of the light shielding layer and a sheet rib in contact with the wall rib to cover an overall area of the light shielding layer except for the openings and having a height smaller than a height of the wall rib.

2. An image display apparatus, comprising:
an electron source substrate having a plurality of electron emitting elements; and
a light emitting substrate having a light emitting layer which emits light in response to electrons emitted from the plurality of electron emitting elements and bombarded on the light emitting layer,
wherein the light emitting substrate is the light emitting substrate according to claim 1.

3. A manufacturing method of a light emitting substrate comprising:
forming a light shielding layer having a plurality of openings on a surface of a substrate;
forming between the openings of the light shielding layer a wall rib having a width smaller than a dimension between two adjacent openings;
forming a sheet rib in contact with the wall rib to cover an overall area of the light shielding layer except for the openings; and
forming a light emitting layer in regions of the substrate divided by the rib structure.

4. The manufacturing method of a light emitting substrate according to claim 3,
wherein, to form the sheet rib, a positive photo paste is applied to an area where the wall rib is not formed so that a photo paste layer is formed, and the light shielding layer is used as a photo mask to expose the photo paste layer to light from a rear surface of the substrate and develop the photo paste layer, so that the photo paste corresponding to positions of the openings of the light shielding layer is removed.
